(19) United States
(12) Patent Application Publication
(10) Pub. No.: US 2012/0285501 A1
(43) Pub. Date: Nov. 15, 2012

(54) INTEGRATED BACK-SHEET FOR BACK CONTACT PHOTOVOLTAIC MODULE

(75) Inventors: CHEN QIAN ZHAO, Newark, DE (US); THOMAS D. LANTZER, Wake Forest, NC (US); ALAN F. GREEN, Wilmington, DE (US)

(73) Assignee: E.I. DU PONT DE NEMOURS AND COMPANY, Wilmington, DE (US)

(21) Appl. No.: 13/285,233

(22) Filed: Oct. 31, 2011

Related U.S. Application Data
(60) Provisional application No. 61/427,914, filed on Dec. 29, 2010.

(51) Int. Cl. H05K 1/05; H01L 31/05

(52) U.S. Cl. 136/244; 174/258

(57) ABSTRACT

An integrated back-sheet for a solar cell module with a plurality of electrically connected solar cells and a back-contact solar module made with the integrated back-sheet are provided. The back-sheet comprises a homogeneous polymeric substrate with a thickness of at least 0.25 mm. The polymeric substrate comprises 20 to 95 weight percent chlorosulfonated polyolefin and 1 to 50 weight percent of adhesive, based on the weight of the polymeric substrate. The adhesive is selected from thermoplastic and thermoset polymer adhesives and rosin based tackifiers. The integrated back-sheet also includes a plurality of electrically conductive metal wires disposed directly on a surface of the homogeneous polymeric substrate, and the opposite surface of the polymeric substrate is an exposed surface.

### CLAIM OF PRIORITY

This application claims priority from U.S. Provisional Application No. 61/427,914 filed on Dec. 29, 2010, entitled “Photovoltaic Module with Chlorosulfonated Polyolefin Layer.”

### BACKGROUND OF THE INVENTION

1. Field of the Disclosure

The present invention relates to back-sheets for photovoltaic cells and modules, and more particularly to back-sheets with integrated electrically conductive circuits, and back-contact photovoltaic modules with electrically conductive circuits integrated into the back of the modules.

2. Description of the Related Art

A photovoltaic cell converts radiant energy, such as sunlight, into electrical energy. In practice, multiple photovoltaic cells are electrically connected together in series or in parallel and are protected within a photovoltaic module or solar module.

As shown in FIG. 1, a photovoltaic module 10 comprises a light-transmitting substrate 12 or front sheet, a front encapsulant layer 14, an active photovoltaic cell layer 16, a rear encapsulant layer 18 and a back-sheet 20. The light-transmitting substrate is typically glass or a durable light-transmitting polymer film. The transparent front sheet (also know as the incident layer) comprises one or more light-transmitting sheets or film layers. The light-transmitting front sheet may be comprised of glass or plastic sheets, such as, polycarbonate, acrylics, polyacrylate, cyclic polyolefins, such as ethylene norbornene polymers, polystyrene, polyamides, polyesters, silicon polymers and copolymers, fluoropolymers and the like, and combinations thereof. The front and back encapsulant layers 14 and 18 adhere the photovoltaic cell layer 16 to the front and back sheets, they seal and protect the photovoltaic cells from moisture and air, and they protect the photovoltaic cells against physical damage. The encapsulant layers 14 and 18 are typically comprised of a thermoplastic or thermosetting resin such as ethylene-vinyl acetate copolymer (EVA). The photovoltaic cell layer 16 is made up of any type of photovoltaic cell that converts sunlight to electric current such as single crystal silicon solar cells, polycrystalline silicon solar cells, microcrystal silicon solar cells, amorphous silicon-based solar cells, copper indium (gallium) diselenide solar cells, cadmium telluride solar cells, compound semiconductor solar cells, dye sensitized solar cells, and the like. The back-sheet 20 provides structural support for the module 10, it electrically insulates the module, and it helps to protect the module wiring and other components against the elements, including heat, water vapor, oxygen and UV radiation. The module layers need to remain intact and adhered for the service life of the photovoltaic module, which may extend for multiple decades.

Photovoltaic cells typically have electrical contacts on both the front and back sides of the photovoltaic cells. However, contacts on the front sunlight receiving side of the photovoltaic cells can cause up to a 10% shading loss.

In back-contact photovoltaic cells, all of the electrical contacts are moved to the back side of the photovoltaic cell. With both the positive and negative polarity electrical contacts on the back side of the photovoltaic cells, electrical circuitry is needed to provide electrical connections to the positive and negative polarity electrical contacts on the back of the photovoltaic cells. U.S. Patent Application No. 2011/0067751 discloses a back-contact photovoltaic module with a back-sheet having patterned electrical circuitry that connects to the back contacts on the photovoltaic cells during lamination of the solar module. The circuitry is formed from a metal foil that is adhesively bonded to a carrier material such as polyester film or Kapton® film. The carrier material may be adhesively bonded to a protective layer such as a backsheet laminate comprised of polyester and fluoropolymer film layers. The layers are provided to bring different properties to the protective back-sheet such as strength, electrical resistance, moisture resistance, and durablility.

PCT Publication No. WO2011/011091 discloses a back-contact solar module with a back-sheet with a patterned adhesive layer with a plurality of patterned conducting ribbons placed thereon to interconnect the solar cells of the module. Placing and connecting multiple conducting ribbons between solar cells is time consuming and difficult to do consistently.

Multilayer laminates have been employed as photovoltaic module back-sheets. One or more of the laminate layers in such back-sheets conventionally comprise a highly durable and long lasting polyvinyl fluoride (PVF) film which is available from E. I. du Pont de Nemours and Company as Tedlar® film. PVF films are typically laminated to other polymer films that contribute mechanical and dielectric strength to the back-sheet, such as polyester films, as for example polyethylene terephthalate (PET) films.

There is a need for durable and economical back-sheets for a back-contact photovoltaic module with integrated conductive circuitry.

### SUMMARY

An integrated back-sheet for a solar cell module with a plurality of electrically connected solar cells is provided. The back-sheet comprises a homogeneous polymeric substrate having opposite first and second surfaces. The polymeric substrate has a thickness of at least 0.25 mm, and the polymeric substrate comprises 20 to 95 weight percent chlorosulfonated polyolefin based on the weight of the polymeric substrate, and 1 to 50 weight percent of adhesive based on the weight of the polymeric substrate. The adhesive is selected from thermoplastic and thermoset polymer adhesives and rosin based tackifiers. The integrated back-sheet also includes a plurality of electrically conductive metal wires disposed directly on the first surface of the homogeneous polymeric substrate. The metal wires are at least partially embedded in the first surface of the polymeric substrate, where the polymeric substrate adhers to the metal wires. The second surface of the homogeneous polymeric substrate is an exposed surface.

The homogeneous polymeric substrate preferably has a thickness of from 0.4 to 1.25 mm. The homogeneous polymeric substrate preferably comprises 25 to 90 weight percent chlorosulfonated polyethylene, and 5 to 35 weight percent of adhesive selected from thermoplastic polymer adhesives and rosin based tackifiers. The chlorosulfonated polyolefin may be chlorosulfonated polyethylene having the formula

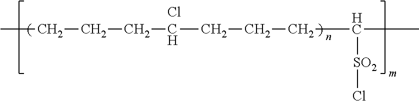

where m and n are positive integers of about 5-25. The chlorosulfonated polyethylene preferably has a weight average molecular weight of about 75,000 to 300,000. The adhesive of the polymeric substrate of the integrated back-sheet may comprise an ethylene copolymer.

The polymeric substrate of the integrated back-sheet may further comprise 10 to 70 weight percent of inorganic particulates based on the weight of the polymeric substrate. The inorganic particulates are preferably selected from the group of calcium carbonate, titanium dioxide, kaolin and clays, alumina trihydrate, talc, silica, antimony oxide, magnesium hydroxide, barium sulfate, mica, vermiculite, alumina, titania, wollastinite, boron nitride, and combinations thereof.

The electrically conductive metal wires of the integrated back-sheet may be comprised of metal selected from copper, nickel, tin, silver, aluminum, and combination thereof. The conductive metal wires may comprise a plurality of metal wires each extending at least two times the length of a solar cell in the solar cell module. The metal wires may be ribbon shaped metal wires having a width and thickness wherein the wire width is at least three times greater than the wire thickness. Preferably, the plurality of electrically conductive metal wires adhered to the first side of the polymeric substrate each have a cross sectional area of at least 70 square mils along their length, are substantially parallel to each other, do not touch each other, and extend at least two times the length of a solar cell in the solar cell module.

A back-contact solar module is also disclosed. The module comprises a front light emitting substrate. A solar cell array of at least four solar cells are provided that each have a front light receiving surface, an active layer that generates an electric current when the front light receiving surface is exposed to light, and a rear surface opposite the front light receiving surface. The rear surface has positive and negative polarity electrical contacts thereon, and the front light receiving surface of each of the solar cells of the solar cell array are disposed on the front light emitting substrate. A homogeneous polymeric substrate having opposite first and second surfaces is provided. The polymeric substrate has a thickness of at least 0.25 mm, and comprises 20 to 95 weight percent chlorosulfonated polyolefin based on the weight of the polymeric substrate, and 1 to 50 weight percent of adhesive based on the weight of the polymeric substrate. The adhesive may be selected from thermoplastic and thermoset polymer adhesives and rosin based tackifiers. The second surface of the homogeneous polymeric substrate forms an exposed surface of the solar module. A plurality of electrically conductive metal wires are disposed directly on the first surface of the homogeneous polymeric substrate. The metal wires are at least partially embedded in the first surface of the polymeric substrate and the homogeneous polymeric substrate is adhered to the metal wires. The positive and negative polarity electrical contacts on the rear surface of the solar cells of the solar cell array are physically and electrically connected to the electrically conductive metal wires disposed on the first surface of the polymeric substrate.

The back-contact solar module may further comprise a polymeric interlayer dielectric layer having opposite first and second sides disposed between the electrically conductive metal wires on the back-sheet and the rear surface of the solar cells of the solar cell array. The interlayer dielectric layer is preferably adhered on its first side to the rear surface of the solar cells of the solar cell array and on its second side to the first side of the polymeric substrate over the conductive metal wires. The polymeric interlayer dielectric layer may have openings arranged in a plurality of columns. The plurality of columns of openings in the interlayer dielectric layer are arranged over the conductive wires adhered to the first side of the polymeric substrate such that the openings in each column of openings are aligned with and over one of the plurality of electrically conductive wires. The openings in the interlayer dielectric layer are aligned with the positive and negative polarity contacts on the rear surfaces solar cells of the solar cell array. The positive and negative polarity electrical contacts on the rear surfaces of the solar cells are electrically connected to the conductive wires through the openings in the polymeric interlayer dielectric layer.

The homogeneous polymeric substrate of the back-contact solar module may comprises 25 to 90 weight percent chlorosulfonated polyethylene, and 5 to 35 weight percent of adhesive selected from thermoplastic polymer adhesives and rosin based tackifiers. The chlorosulfonated polyethylene may have the formula

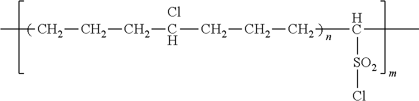

where m and n are positive integers of about 5-25. The chlorosulfonated polyethylene preferably has a weight average molecular weight of about 75,000 to 300,000.

### BRIEF DESCRIPTION OF THE DRAWING

The detailed description will refer to the following drawings, wherein like numerals refer to like elements:

FIG. 1 is cross-sectional view of a conventional solar cell module.

FIGS. 2a and 2b are schematic plan views of the back side of arrays of back-contact solar cells.

FIGS. 3 is a schematic representations of a back-sheet with integrated wires.

FIGS. 4a-4c are cross-sectional views illustrating one disclosed process for forming a back-contact solar cell module in which a back-sheet with integrated conductive wires are connected to the back contacts of solar cells.

FIGS. 5a-5f illustrate steps of a process for forming a back-contact solar cell module in which an array of back-contact solar cells are electrically connected in series by conductive wires that are integrated into the back-sheet of the solar cell module.

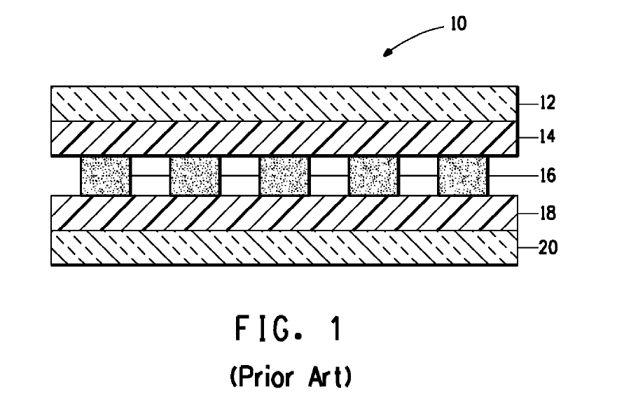

### DETAILED DESCRIPTION

To the extent permitted by the United States law, all publications, patent applications, patents, and other references mentioned herein are incorporated by reference in their entirety.

The materials, methods, and examples herein are illustrative only and the scope of the present invention should be judged only by the claims.

### Definitions

The following definitions are used herein to further define and describe the disclosure.

The terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

The terms “a” and “an” include the concepts of “at least one” and “one or more than one”.

Unless stated otherwise, all percentages, parts, ratios, etc., are by weight.

When the term “about” is used in describing a value or an end-point of a range, the disclosure should be understood to include the specific value or end-point referred to.

As used herein, the terms “sheet”, “layer” and “film” are used in their broad sense interchangeably. A “frontsheet” is a sheet, layer or film on the side of a photovoltaic module that faces a light source and may also be described as an incident layer. Because of its location, it is generally desirable that the frontsheet has high transparency to the incident light. A “back-sheet” is a sheet, layer or film on the side of a photovoltaic module that faces away from a light source, and is generally opaque. In some instances, it may be desirable to receive light from both sides of a device (e.g., a bifacial device), in which case a module may have transparent layers on both sides of the device.

“Encapsulant” layers are used to encase the fragile voltage-generating photoactive layer so as to protect it from environmental or physical damage and hold it in place in the photovoltaic module. Encapsulant layers may be positioned between the solar cell layer and the frontsheet layer, between the solar cell layer and the back-sheet layer, or both. Suitable polymer materials for these encapsulant layers typically possess a combination of characteristics such as high transparency, high impact resistance, high penetration resistance, high moisture resistance, good ultraviolet (UV) light resistance, good long term thermal stability, adequate adhesion strength to frontsheets, backsheets, other rigid polymeric sheets and cell surfaces, and good long term weatherability.

As used herein, the terms “photoactive” and “photovoltaic” may be used interchangeably and refer to the property of converting radiant energy (e.g., light) into electric energy.

As used herein, the terms “photovoltaic cell” or “photoactive cell” or “solar cell” mean an electronic device that converts radiant energy (e.g., light) into an electrical signal. A photovoltaic cell includes a photoactive material layer that may be an organic or inorganic semiconductor material that is capable of absorbing radiant energy and converting it into electrical energy. The terms “photovoltaic cell” or “photoactive cell” or “solar cell” are used herein to include photovoltaic cells with any types of photoactive layers including, crystalline silicon, polycrystalline silicon, microcrystal silicon, and amorphous silicon-based solar cells, copper indium (gallium) diselenide solar cells, cadmium telluride solar cells, compound semiconductor solar cells, dye sensitized solar cells, and the like.

As used herein, the term “photovoltaic module” or “solar module” (also “module” for short) means an electronic device having at least one photovoltaic cell protected on one side by a light transmitting front sheet and protected on the opposite side by an electrically insulating protective back-sheet.

The term “copolymer” is used herein to refer to polymers containing copolymerized units of two different monomers (a dipolymer), or more than two different monomers.

Disclosed herein are integrated back-sheets for back-contact solar cell modules and processes for forming such integrated back-sheets. Also disclosed are back-contact solar modules with an integrated conductive circuitry and processes for forming such back-contact solar modules with integrated circuitry.

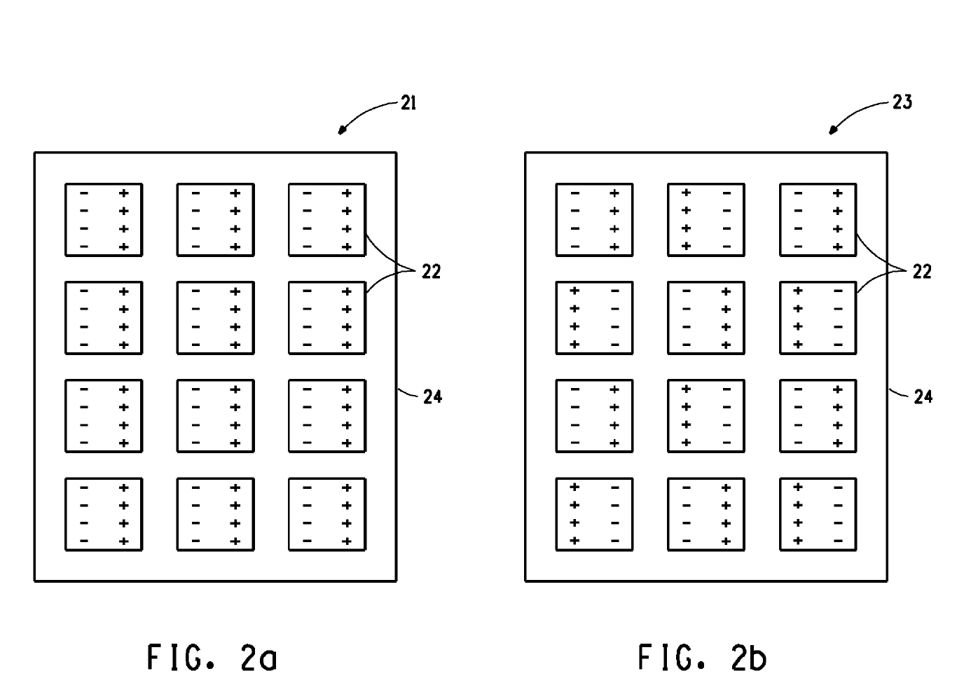

Arrays of back-contact solar cells are shown in FIGS. 2a and 2b. The disclosed integrated back-sheet is useful for protecting and electrically connecting back-contact solar cell arrays like those shown in FIGS. 2a and 2b as well as with arrays of other types of back-contact solar cells. The solar cell array 21 includes multiple solar cells 22, such as single crystal silicon solar cells. The front side (not shown) of each solar cell 22 is adhered to an encapsulant layer 24 that is or will be preferably adhered to a transparent front sheet (not shown) of the solar module. Solar modules with an array of twelve solar cells 22 are shown in FIGS. 2a and 2b, but the disclosed integrated back-sheet is useful as a back-sheet for back-contact solar modules having solar cell arrays of anywhere from four to more than 100 solar cells.

Each of the solar cells 22 has multiple positive and negative polarity contacts on back side of the solar cell. The contacts on the back side of the solar cells are typically made of a metal to which electric contacts can be readily formed, such as silver or platinum contact pads. The contacts are typically formed from a conductive paste comprising an organic medium, glass frit and silver particles, and optionally inorganic additives, which is fired at high temperature to form metal contact pads. The solar cells shown in FIGS. 2a and 2b each have a column of four negative contacts and a column of four positive contacts, but it is contemplated that the solar cells could have multiple columns of negative and positive contacts and that each column could have anywhere form two to more than twenty contacts. It is also contemplated that the positive and negative contacts can be formed in arrangements other than straight columns. In the solar cell array shown in FIG. 2a, the contacts of each cell are arranged in the same way. The arrangement shown in FIG. 2a is used with the disclosed integrated back-sheet when the back-sheet is used to connect the cells in parallel. Alternatively, the solar cells in each column of the array can be arranged such that the alternating cells in each column are flipped 180 degrees as shown in FIG. 2b. The solar cell array 23 shown in FIG. 2b is used with the disclosed integrated back-sheet when the back-sheet is used to electrically connect the solar cells in series.

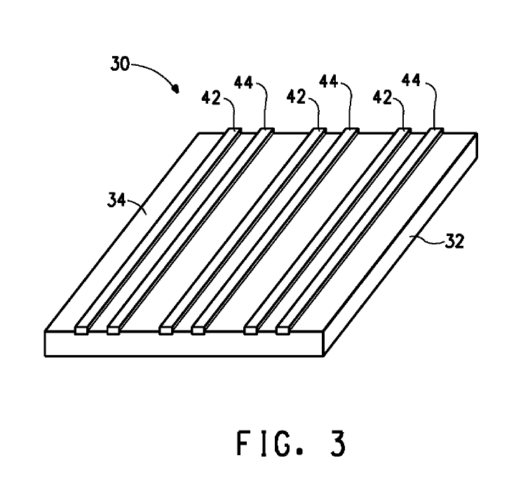

FIG. 3 shows an embodiment of the disclosed integrated back-sheet. The back-sheet 30 shown in FIG. 3 is comprised of a single homogeneous polymeric substrate. The polymeric substrate 32 may comprise a polymer film or sheet. The polymeric substrate is comprised of chlorosulfonated polyolefin polymer. By “polyolefin” is meant homopolymers and copolymers of C₂-C₈ alpha-monoolefins, including graft copolymers. The copolymers may be dipolymers or higher order copolymers, such as terpolymers or tetrapolymers. Particularly useful examples include homopolymers of C₂-C₃ alpha monoolefins, copolymers of ethylene and carbon monoxide, and copolymers of ethylene and at least one ethylenically unsaturated monomer selected from the group consisting of C₃-C₁₀ alpha monoolefins, C₁-C₁₂ alkyl esters of unsaturated C₃-C₂₀ monocarboxylic acids, unsaturated C₃-C₂₀ mono-or dicarboxylic acids, anhydrides of unsaturated C₄-C₈ dicarboxylic acids, and vinyl esters of saturated C₂-C₁₈ carboxylic acids. Specific examples of these polymers include polyethylene, polypropylene, ethylene vinyl acetate copolymers, ethylene acrylic acid copolymers, ethylene methacrylic acid copolymers, ethylene methyl acrylate copolymers, ethylene methyl methacrylate copolymers, ethylene nbutyl methacrylate copolymers, ethylene glycidyl methacrylate copolymers, graft copolymers of ethylene and maleic anhydride, graft copolymers of propylene and maleic anhydride, and copolymers of ethylene with propylene, butene, 3-methyl-l-pentene, hexene, or octene. Preferred olefin polymers are polyethylene, ethylene propylene copolymers, ethylene butene copolymers, ethylene octene copolymers, copolymers of ethylene and acrylic acid, copolymers of ethylene and methacrylic acid, and copolymers of ethylene and vinyl acetate. The olefin polymers have number average molecular weights within the range of 1,000 to 300,000.

The preferred chlorosulfonated polyolefin for the substrate is a chlorosulfonated polyethylene (CSPE) polymer. The polymeric substrate 32 has opposite first and second planar surfaces. Electrically conductive metal circuits are disposed directly on the first surface of the polymeric substrate and stick to the polymeric substrate. The electrically conductive metal circuits may comprise wires 40 and 42 that are preferably partially embedded in the first surface 34 of the polymeric substrate. The opposite second surface of the polymeric substrate (not shown) forms an exposed exterior surface of the integrated back-sheet and of the photovoltaic module to which the integrated back-sheet is attached.

In one embodiment, a chlorosulfonated polyolefin containing sheet is provided that is comprised of 25% by weight or more of chlorosulfonated polyolefin, preferably 30% by weight or more of chlorosulfonated polyolefin, and more preferably 40% by weight or more of chlorosulfonated polyolefin. The chlorosulfonated polyolefin may be an elastomer or synthetic rubber. The chlorosulfonated polyolefin is a polyolefin that has a chlorine content of about 15-60% by weight and preferably about 25-45% by weight, and that has a sulfur content to about 0.1-4% by weight and preferably about 0.7-1.5% by weight. Chlorosulfonated polyolefins are formed by the reaction of polyolefins with chlorine and sulfuryl chloride or sulfur dioxide in solution. Reactive extrusion and solventless processes have also been disclosed, for example in U.S. Pat. No. 3,347,835 and in U.S. Pat. No. 4,554,326. In addition, chlorosulfonation of solvent-swollen ethylene polymers in fluids consisting of fluorocarbons having 1-4 carbon atoms are known.

In a preferred embodiment, the chlorosulfonated polyolefin sheet or film is comprised of chlorosulfonated polyethylene (CSPE). The CSPE containing sheet is comprised of 25% by weight or more of CSPE, preferably 30% by weight or more of CSPE, and more preferably 40% by weight or more of CSPE. The cholrosulfonated polyethylene has a chlorine content of about 15-60% by weight and preferably about 25-45% by weight, and has a sulfur content to about 0.1-4.0% by weight and preferably about 0.7-1.5% by weight. The CSPE polymer is a partially chlorinated polyethylene containing sulfonyl chloride groups. CSPE is a synthetic rubber or elastomer that is also referred to as CSM and has been sold under the Hypalon® trademark of E. I. du Pont de Nemours and Company.

One useful chlorosulfonated polyethylene has the formula

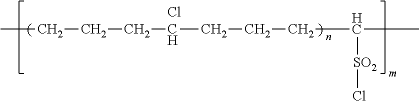

where m and n are positive integers of about 5-25. The polymer has a weight average molecular weight of about 75,000 to 300,000, and preferably about 100,000 to 150,000. Molecular weight, as used herein, is determined by gel permeation chromatography using polymethyl methacrylate as a standard.

The thickness of the chlorosulfonated polyolefin containing substrate layer ranges from about 0.25 mm to about 1.5 mm (about 10 to about 59 mils) or more, and more preferably about 0.4 mm to about 1.25 mm (about 16 to about 49 mils), and more preferably about 0.5 mm to about 1.0 mm (20 to 39 mils). The chlorosulfonated polyolefin containing substrate thickness in embodiments where the substrate layer is adhered to a separate interlayer dielectric layer or encapsulant layer on the back of the solar cell is preferably within the range of about 0.4 mm to about 1.0 mm (about 16 mils to about 39 mils).

In one preferred embodiment, a chlorosulfonated polyolefin containing photovoltaic module substrate layer is comprised of a chlorosulfonated polyolefin combined with one or more tackifiers or thermoplastic polymer adhesives. For example, CSPE and tackifiers or thermoplastic polymer adhesives may be mixed by known compounding processes. In one aspect, the CSPE containing sheet comprises comprises 20 to 95% by weight of CSPE as described above, and 1 to 50% by weight of one or more of tackifiers and thermoplastic polymer adhesives, and more preferably and 5 to 30% by weight of one or more of tackifiers and thermoplastic polymer adhesives, and even more preferably and 10 to 30% by weight of one or more of tackifiers and thermoplastic polymer adhesives. The tackifiers and/or thermoplastic polymer adhesives serve to improve the adhesion of the CSPE containing sheet to the conductive circuit and to the interlayer dielectric layer or the encapsulant layer of the solar cell of the photovoltaic module.

Tackifiers useful in the disclosed chlorosulfonated polyolefin containing back-sheet substrate include hydrogenated rosin-based tackifiers, acrylic low molecular weight tackifiers, synthetic rubber tackifiers, hydrogenated polyolefin tackifiers such as polyterpene, and hydrogenated aromatic hydrocarbon tackifiers. Two preferred hydrogenated rosin-based tackifiers include FloraRez 485 glycerol ester hydrogenated rosin tackifier from Florachem Corporation and Stabelite Ester-E hydrogenated rosin-based tackifier from Eastman Chemical.

Thermoplastic polymer adhesives useful in the disclosed chlorosulfonated polyolefin containing back-sheet substrate include ethylene copolymer adhesives such as ethylene acrylic acid copolymers, ethylene vinyl acetate copolymers, and ethylene methacrylate copolymers. Ethylene copolymer adhesives that may be used as the thermoplastic adhesive may be from the following groups:

ethylene-C₁₋₄ alkyl methacrylate copolymers and ethylene-C₁₋₄ alkyl acrylate copolymers, for example, ethylene-methyl methacrylate copolymers, ethylene-methyl acrylate copolymers, ethylene-ethyl methacrylate copolymers, ethylene-ethyl acrylate copolymers, ethylene-propyl methacrylate copolymers, ethylene-propyl acrylate copolymers, ethylene-butyl methacrylate copolymers, ethylene-butyl acrylate copolymers, and mixtures of two or more copolymers thereof, wherein copolymer units resulting from ethylene account for 50%-99%, preferably 70%-95%, by total weight of each copolymer;

ethylene-methacrylic acid copolymers, ethylene-acrylic acid copolymers, and blends thereof, wherein copolymer units resulting from ethylene account for 50-99%, preferably 70-95%, by total weight of each copolymer;

ethylene-maleic anhydride copolymers, wherein copolymer units resulted from ethylene account for 50-99%, preferably 70-95%, by total weight of the copolymer;

polybasic polymers formed by ethylene with at least two co-monomers selected from C₁ alkyl methacrylate, C₁₄ alkyl acrylate, ethylene-methacrylic acid, ethylene-acrylic acid and ethylene-maleic anhydride, non-restrictive examples of which include, for example, terpolymers of ethylene-methyl acrylate-methacrylic acid (wherein copolymer units resulting from methyl acrylate account for 2-30% by weight and copolymer units resulting from methacrylic acid account for 1-30% by weight), terpolymers of ethylene-butyl acrylate-methacrylic acid (wherein copolymer units resulting from butyl acrylate account for 2-30% by weight and copolymer units resulting from methacrylic acid account for 1-30% by weight), terpolymers of ethylene-propyl methacrylate-acrylic acid (wherein copolymer units resulting from propyl methacrylate account for 2-30% by weight and copolymer units resulting from acrylic acid account for 1-30% by weight), terpolymers of ethylene-methyl acrylate-acrylic acid (wherein copolymer units resulting from methyl acrylate account for 2-30% by weight and copolymer units resulted from acrylic acid account for 1-30% by weight), terpolymers of ethylene-methyl acrylate-maleic anhydride (wherein copolymer units resulting from methyl acrylate account for 2-30% by weight and copolymer units resulting from maleic anhydride account for 0.2-10% by weight), terpolymers of ethylene-butyl acrylate-maleic anhydride (wherein copolymer units resulting from butyl acrylate account for 2-30% by weight and copolymer units resulted from maleic anhydride account for 0.2-10% by weight), and terpolymers of ethylene-acrylic acid-maleic anhydride (wherein copolymer units resulting from acrylic acid account for 2-30% by weight and copolymer units resulting from maleic anhydride account for 0.2-10% by weight);

copolymers formed by ethylene and glycidyl methacrylate with at least one co-monomer selected from C₁₄ alkyl methacrylate, C₁₋₄ alkyl acrylate, ethylene-methacrylic acid, ethylene-acrylic acid, and ethylene-maleic anhydride, non-restrictive examples of which include, for example, terpolymers of ethylene-butyl acrylate-glycidyl methacrylate, wherein copolymer units resulting from butyl acrylate account for 2-30% by weight and copolymer units resulting from glycidyl methacrylate account for 1-15% by weight;

and blends of two or more above-described materials.

Another ethylene copolymer that may included in the CSPE containing photovoltaic module back-sheet substrate is ethylene vinyl acetate copolymer. Other thermoplastic adhesives that may be utilized in the CSPE containing back-sheet substrate includes polyurethanes, acrylic hot melt adhesives, synthetic rubber, and other synthetic polymer adhesives.

The chlorosulfonated polyolefin back-sheet may further comprise 10% to 70% by weight of inorganic particulates, and more preferably 40% to 65% of inorganic particulates. The inorganic particulates preferably comprise fillers, pigments and other inert additives.

Useful filler materials include calcium carbonate, kaolin and clays, alumina trihydrate, talc (magnesium silicate hydroxide), silica, antimony oxide, magnesium hydroxide, barium sulfate, mica, vermiculite, alumina, titania, acicular titanium dioxide, wollastinite and boron nitride. The filler materials may serve to add reinforcement to the sheet or reduce the overall cost of the CSPE containing sheet. Platelet shaped fillers such as mica and talc and/or fibrous fillers may reinforce and strengthen the film. Preferred fillers have an average particle size less than 100 microns and preferably less than 10 microns. If the particle size is too large, defects, voids and surface roughness of the film may be a problem. If the particle size is too small, the particles may be difficult to disperse and the viscosity may be excessively high. Generally speaking, average particle sizes between 0.5 to 100 microns are preferred.

Pigments such as titanium dioxide serve to make the sheet whiter, more opaque and more reflective which may be desirable in a photovoltaic module back-sheet layer.

The chlorosulfonated polyolefin containing back-sheet substrate may comprise additional additives including, but are not limited to, plasticizers such as polyethylene glycol, processing aides, flow enhancing additives, lubricants, dyes, flame retardants, impact modifiers, nucleating agents to increase crystallinity, antiblocking agents such as silica, thermal stabilizers, hindered amine light stabilizers (HALS), UV absorbers, UV stabilizers, dispersants, surfactants, adhesives, primers, and reinforcement additives, such as glass fiber and the like. Compounds that help to catalyze cross-linking reactions in CSPE such as inorganic oxides like magnesium oxide may also be used. Such additives typically are added in amounts of less than 3% by weight of a CSPE containing substrate with the total of such additional additives comprising less than 10% by weight of the CSPE containing substrate and more preferably less than 5% by weight of the CSPE containing substrate.

Conductive wires, such as the substantially parallel pairs of electrically conductive wires 40 and 42 may be adhered directly to the surface of the back-sheet 32 that will face the back of the solar cells of the solar cell array. Three pairs of wires 40 and 42 are shown in FIG. 3, but it is contemplated that more or fewer pairs of wires could be used depending upon the number of columns of solar cells in the solar cell array to which the integrated back-sheet is applied, and depending on the number of columns of back contacts on each of the solar cells. It is also contemplated that the spacing of the wires will depend upon the splicing of the columns of solar cells in the array to which the integrated back-sheet is applied, and on the arrangement and spacing of the columns of back contacts on each of the solar cells. It is contemplated that a single back-sheet will cover the back of the entire solar cell array, but is possible for form the solar module back from multiple back-sheet substrates.

The wires 40 and 42 are preferably conductive metal wires. The metal wires are preferably comprised of metal selected from copper, nickel, tin, silver, aluminum, indium, lead, and combinations thereof. In one embodiment, the metal wires are coated with tin, nickel or a solder and/or flux material. The conductive wires may be coated with an electrically insulating material such as a plastic sheath so as to help prevent short circuits in the solar cells when the wires are positioned over the back of an array of solar cells. Were the conductive wires are coated with an insulating material, the insulating material can be formed with breaks where the wires are exposed to facilitate the electrical connection of the wires to the back contacts of the solar cells.

The electrically conductive wires preferably each have a cross sectional area of at least 70 square mils along their length, and more preferably have a cross sectional area of at least 100 square mils along their length. Preferably, the electrically conductive wires have a thickness (depth) of at least 75 mils, and preferably a thickness of about 100 mils to about 200 mils, and more preferably about 150 mils to about 170 mils. The electrically conductive wires of the integrated back-sheet may have any cross sectional shape, but ribbon shaped wires having a width and thickness where the wire width is at least three times greater than the wire thickness, and more preferably where the wire width is 3 to 15 times the wire thickness, have been found to be especially well suited for use in the integrated back-sheet because wider wires makes it easier to align the wires with the back contacts of the solar cells when the integrated back-sheet is formed and applied to an array of back-contact solar cells. Solar cell tabbing wire such as aluminum or copper tabbing wire may be used. In a preferred embodiment, the conductive wires are at least partially embedded in the surface of the chlorosulfonated polyolefin containing back-sheet substrate. Preferably, the wires are partially embedded in the back-sheet substrate in order to securely attach the wires to the back-sheet. In a preferred embodiment, the wires are embedded to at least 20% of their thickness in the surface of the back-sheet, and more preferably to at least 50% of the wire thickness. A top surface of the wires should remain exposed so that electrical contacts can be formed between the solar cell back contacts and the wire circuits of the back-sheet. In FIG. 3, the wires are shown as pairs of longitudinally extending wires, but the wires can be fixed to the surface of the back-sheet in other arrangements depending upon the arrangement of the back contacts on the solar cells of the solar cell array.

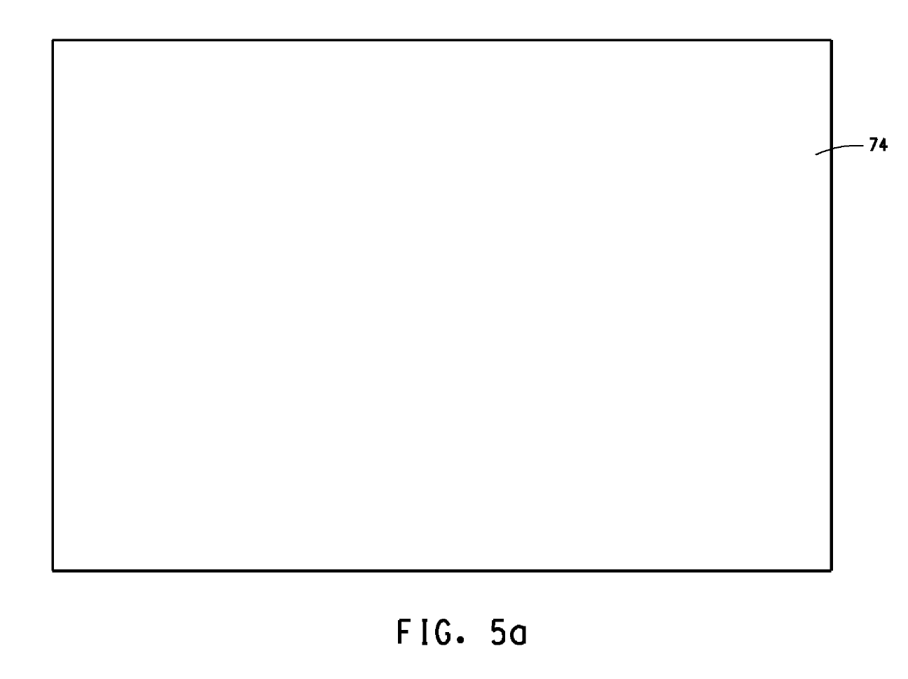

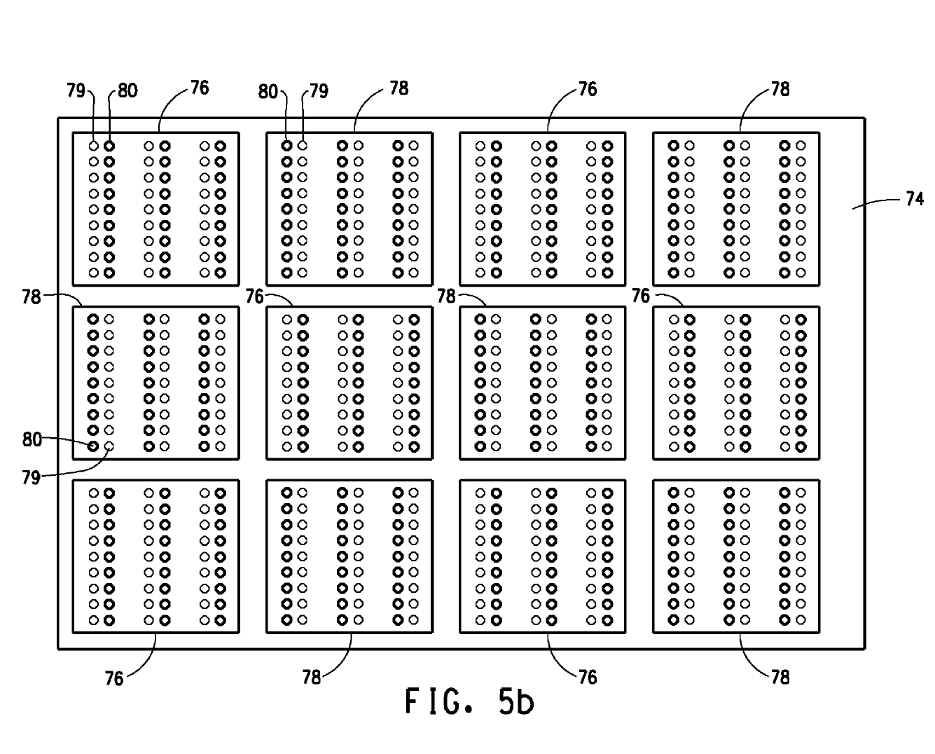

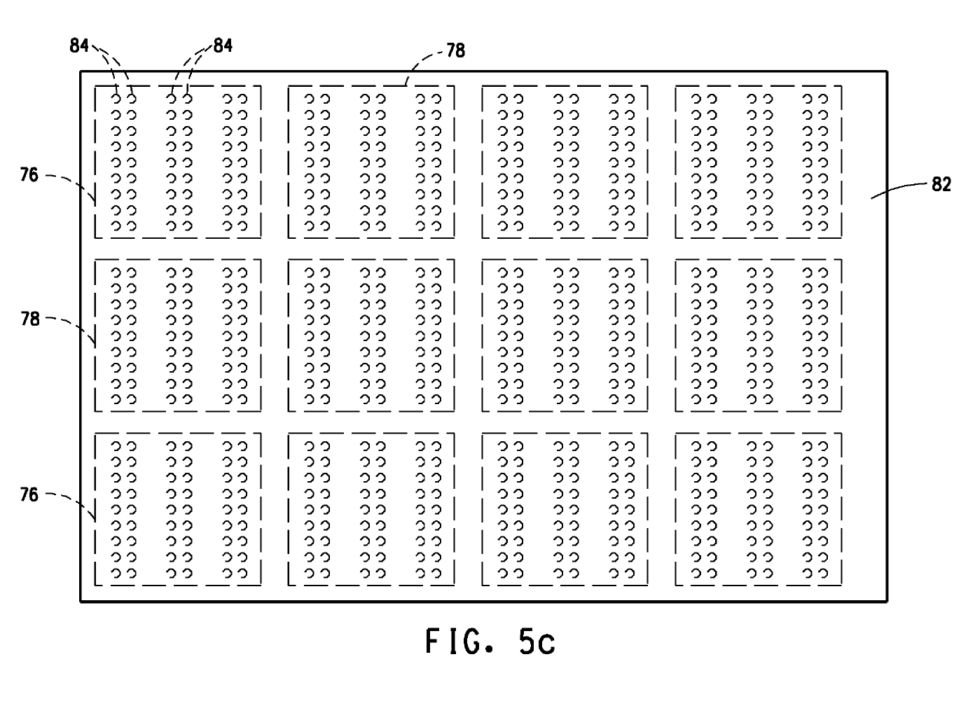

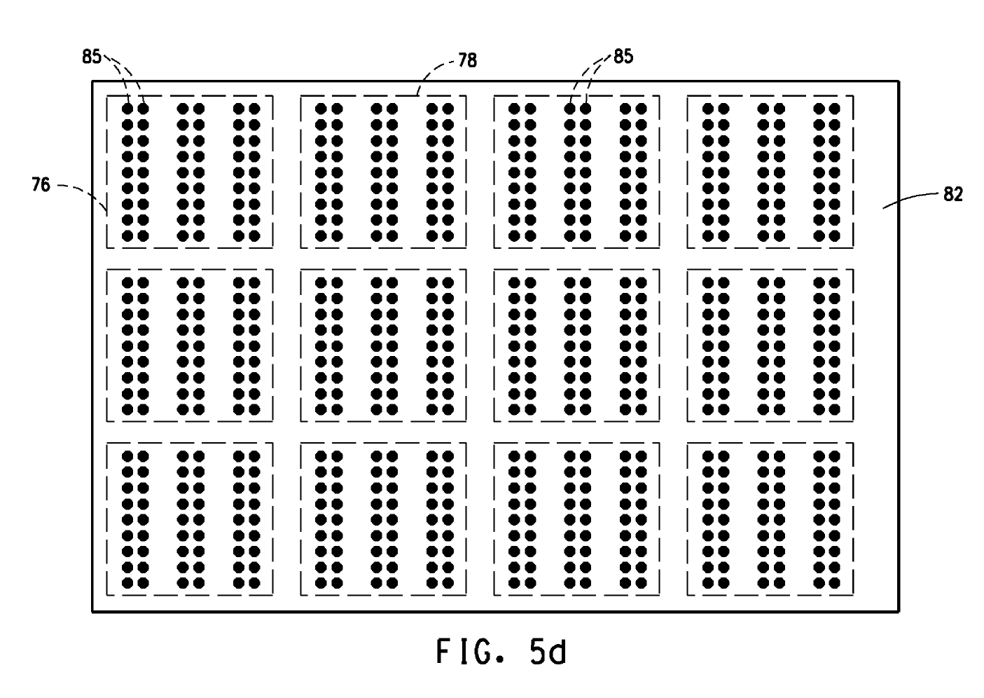

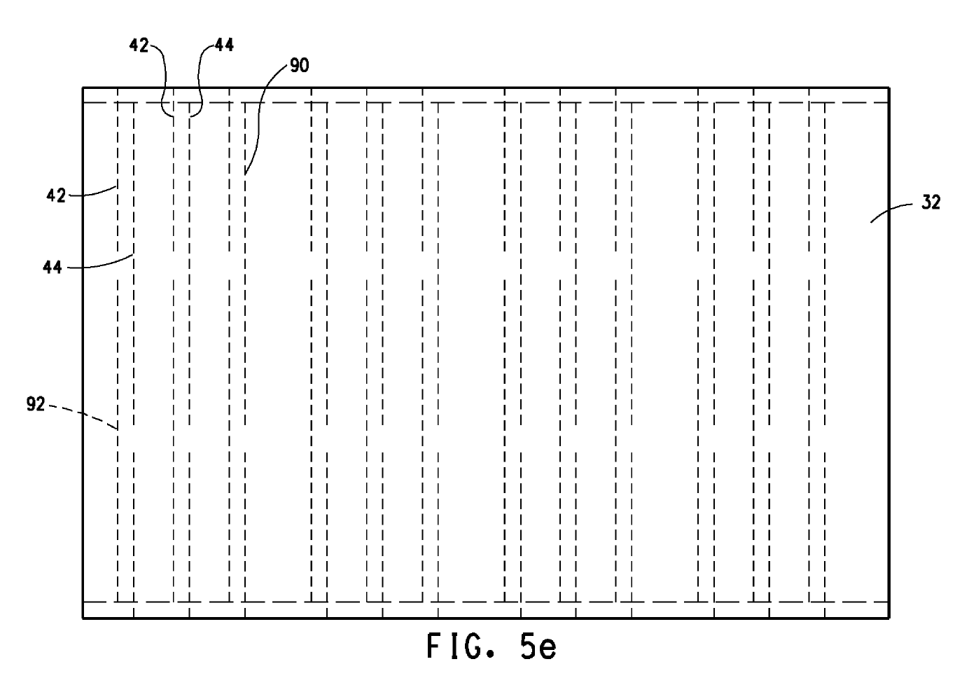

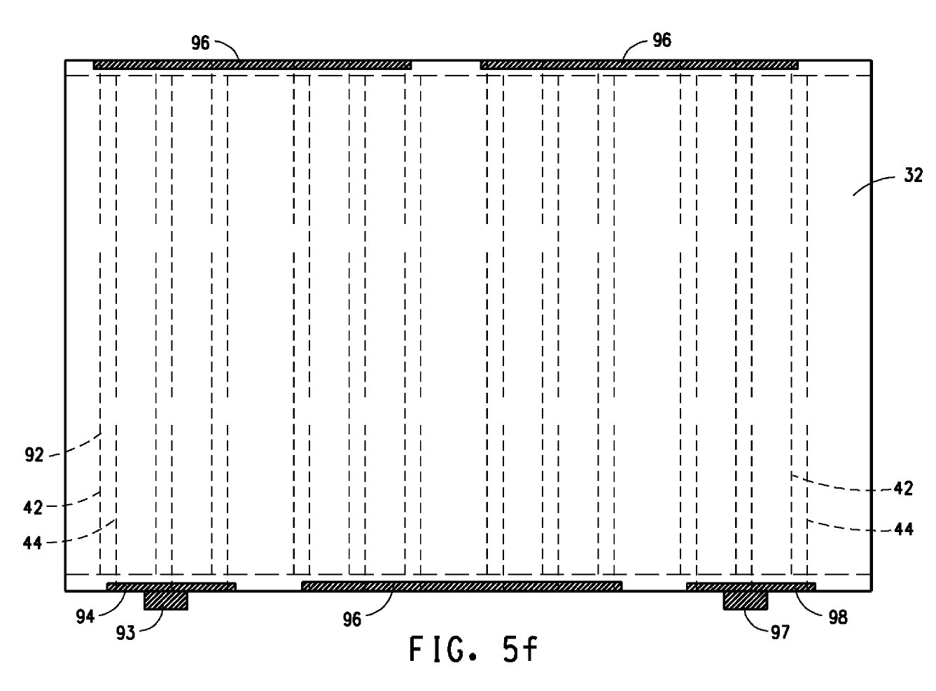

The conductive wires on the integrated back-sheet should be long enough to extend over multiple solar cells,*and they are preferably long enough to cover all of the solar cells in a column of solar cells in the solar cell array to which the integrated back-sheet is applied. The wires can be attached to the surface of the back-sheet by a batch hot pressing process or by a continuous roll-to-roll process where the electrically conductive wires are continuously fed into a heated nip where the wires are brought into contact with the chlorosulfonated polyolefin containing back-sheet substrate and adhered to the substrate by heating the wires and/or the substrate at the nip so as to make the back-sheet substrate surface tacky. Alternatively, the chlorosulfonated polyolefin containing back-sheet substrate can be extruded with the wires fed into the polymer substrate surface during the extrusion process. In another embodiment, the wires and the wire mounting layer are heated and pressed in a batch press to partially or fully embed the wires into the wire mounting layer. Pressure may also be applied to the wires at a heated nip so as to partially or fully embed the conductive wires in the wire mounting layer.

Where the solar cells of the array will be connected in parallel, the full length wires can be used as shown in FIG. 3 and subsequently connected to a column of solar cells like one of the solar cell columns shown in FIG. 2a. Where the solar cells of the array will be connected in series, the wires are cut at selected points as discussed below with regard to FIG. 5 and connected to a column of solar cells where alternating cells have been flipped by 180 degrees, like one of the columns of solar cells shown in FIG. 2b. Cutting the wires can be performed by a variety of methods including mechanical die cutting, punching, rotary die cutting, mechanical drilling, or laser ablation.

In order to prevent electrical shorting of the solar cells, it may be necessary to apply an electrically insulating dielectric layer between the conductive wires on the back-sheet and the back of the solar cells of the back-contact solar cell array. This dielectric layer is provided to maintain a sufficient electrical separation between the conductive wires and the back of the solar cells. The dielectric layer, known as an interlayer dielectric (ILD), may be applied as a sheet over all of the wires and the wire mounting layer, or as strips of dielectric material just over the electrically conductive wires. It is necessary to form openings in the ILD as for example by die cutting or punching sections of the ILD, that will be aligned over the back contacts and through which the back contacts will be electrically connected to the conductive wires. Alternatively, the ILD maybe applied by screen printing. The printing can be on the cells or over the wires on the back-sheet, and can cover the entire area between the back-sheet and the solar cell array or it may be printed only in the areas where the wires need to be prevented from contacting the back of the solar cells. The ILD can be applied to the wires and the back-sheet or it can be applied to the back of the solar cells before the back-sheet and conductive wires are applied over the back of the solar cell array. Alternatively the ILD may be applied as strips over the wires on the portions of the back side of the solar cells over which the conductive wires will be positioned. The thickness of the ILD will depend in part on the insulating properties of the material comprising the ILD, but preferred polymeric ILDs have a thickness in the range of 5 to 500 microns, and more preferably 10 to 300 microns and most preferably 25 to 200 microns. Where the conductive wires on the back-sheet have a complete insulating coating or sheath, it may be possible to eliminate the ILD between the electrically conductive wires on the integrated back-sheet and the back side of the back-contact solar cells to which the integrated back-sheet is applied.

The ILD is preferably comprised of an insulating material such as a thermoplastic or thermoset polymer. For example, the ILD may be an insulating polymer film such as a polyester, polyethylene or polypropylene film. In one embodiment, the ILD is comprised of a PET polymer film that is coated with or laminated to an adhesive or an encapsulant layer such as an EVA film. Preferably the ILD is comprised of a material that can be die cut or punched, or that can be formed with openings in it. Polymeric materials useful for forming the ILD may also include ethylene methacrylic acid and ethylene acrylic acid, ionomers derived therefrom, or combinations thereof. The ILD may also comprise films or sheets comprising poly(vinyl butyral)(PVB), ethylene vinyl acetate (EVA), poly(vinyl acetal), polyurethane (PU), linear low density polyethylene, polyolefin block elastomers, ethylene acrylate ester copolymers, such as poly(ethylene-co-methyl acrylate) and poly(ethylene-co-butyl acrylate), silicone polymers and epoxy resins. The ionomers are thermoplastic resins containing both covalent and ionic bonds derived from ethylene/acrylic or methacrylic acid copolymers. In some embodiments, monomers formed by partial neutralization of ethylene-methacrylic acid copolymers or ethylene-acrylic acid copolymers with inorganic bases having cations of elements from Groups I, II, or III of the Periodic table, notably, sodium, zinc, aluminum, lithium, magnesium, and barium may be used. The term ionomer and the resins identified thereby are well known in the art, as evidenced by Richard W. Rees, “Ionic Bonding In Thermoplastic Resins”, DuPont Innovation, 1971, 2(2), pp. 1-4, and Richard W. Rees, “Physical 30 Properties And Structural Features Of Surlyn Ionomer Resins”, Polyelectrolytes, 1976, C, 177-197. Other suitable ionomers are further described in European patent EP1781735, which is herein incorporated by reference.

Preferred ethylene copolymers for use in the ILD are included the adhesives described above that can be mixed with the chlorosulfonated polyolefin substrate and are more fully disclosed in PCT Patent Publication No. WO2011/044417 which is hereby incorporated by reference. Such ethylene copolymers are comprised of ethylene and one or more monomers selected from the group of consisting of C1-4 alkyl acrylates, C1-4 alkyl methacrylates, methacrylic acid, acrylic acid, glycidyl methacrylate, maleic anhydride and copolymerized units of ethylene and a comonomer selected from the group consisting of C4-C8 unsaturated anhydrides, monoesters of C4-C8 unsaturated acids having at least two carboxylic acid groups, diesters of C4-C8 unsaturated acids having at least two carboxylic acid groups and mixtures of such copolymers, wherein the ethylene content in the ethylene copolymer preferably accounts for 60-90% by weight. A preferred ethylene copolymer for the ILD includes a copolymer of ethylene and another α-olefin. Ethylene copolymers are commercially available, and may, for example, be obtained from DuPont under the trade-name Bynel®.

The ILD may further contain any additive or filler known within the art. Such exemplary additives include, but are not limited to, plasticizers, processing aides, flow enhancing additives, lubricants, pigments, titanium dioxide, calcium carbonate, dyes, flame retardants, impact modifiers, nucleating agents to increase crystallinity, antiblocking agents such as silica, thermal stabilizers, hindered amine light stabilizers (HALS), UV absorbers, UV stabilizers, anti-hydrolytic agents, dispersants, surfactants, chelating agents, coupling agents, adhesives, primers, reinforcement additives, such as glass fiber, and the like. There are no specific restrictions to the content of the additives and fillers in the wire mounting layer as long as the additives do not produce an adverse impact on the adhesion properties or stability of the layer.

The ILD may be coated with an adhesive on the side of the ILD that will initially be contacted with the conductive wires and back-sheet or that will be initially contacted with the back side of the solar cells, depending upon the order of assembly. Suitable adhesive coatings on the ILD include pressure sensitive adhesives, thermoplastic or thermoset adhesives such as the ethylene copolymers discussed above, or acrylic, epoxy, vinyl butryal, polyurethane, or silicone adhesives. The openings formed in the ILD correspond to arrangement of the solar cell back contacts when the ILD is positioned between the conductive wires of the integrated back-sheet and the back of the solar cell array. Preferably, the openings are formed by punching or die cutting the ILD, but alternatively the ILD can be formed or printed with the openings.

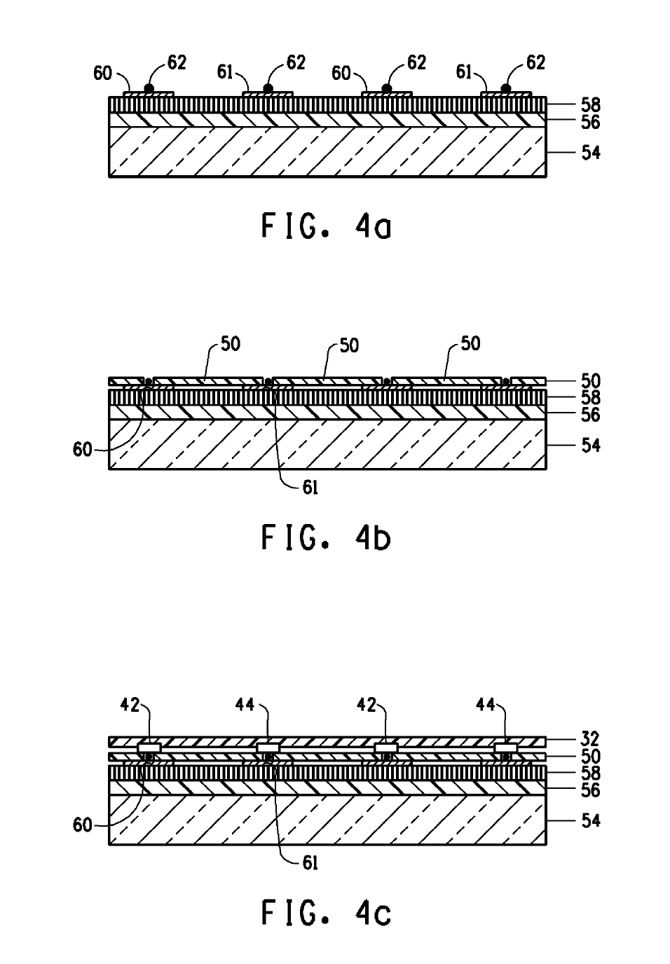

FIGS. 4a-4c illustrate in cross section steps of one process for making a back-contact solar module with an integrated back-sheet. As shown in FIG. 4a, a transparent front sheet 54, made of glass or a polymer such as a durable fluoropolymer, is provided. The transparent front sheet typically has a thickness of from 2 to 4 mm for glass front sheet or 50 to 250 microns for polymer front sheet. A front encapsulant layer 56 may be applied over the front sheet 54. The encapsulant may be comprised of any of the encapsulant or adhesive materials described below with regard to the optional encapsulant between the ILD and the solar cell. The front encapsulant layer typically has a thickness of from 200 to 500 microns and is transparent. A photoactive solar cell 58, such as a crystalline silicon solar cell, is provided on the encapsulant layer 56. The solar cell has all of its electrical contacts on the back side of the solar cell. The best known types of back-contact solar cells are metal wrap through (MWT), metal wrap around (MWA), emitter wrap through (EWT), emitter wrap around (EWA), and interdigitated back contact (IBC). Electrical conductors on the light receiving front side of the solar cell (facing the transparent front sheet) are connected through vias in the solar cell to back side conductive pads 60, while a back side conductive layer (not shown) is electrically connected to back side contact pads 61. The back contact pads are typically silver pads fired on the solar cells from a conductive paste of silver particles and glass frit in an organic carrier medium.

A small portion of an electrically conductive adhesive is provided on each of the contact pads 60 and 61. The portions of conductive adhesive are shown as balls 62 in FIG. 4a. The conductive adhesive may be any known conductive adhesive, such as an adhesive comprised of conductive metal particles, such as silver, nickel, conductive metal coated particles, or conductive carbon suspended in epoxies, acrylics, vinyl butryals, silicones or polyurathanes. Preferred conductive adhesives are aniostropically conductive or z-axis conductive adhesives that are commonly used for electronic interconnections.

FIG. 4b shows the application of an ILD 50 over the back of the solar cell array. FIG. 4c shows the application of the chlorosulfonated polyolefin containing back-sheet, with the electrically conductive ribbon-shaped wires 42 and 44 over the back contacts 60 and 61 of the solar cell 58. The conductive wires 42 and 44 are provided on the back-sheet 32 as described above. Where the ILD 50 is comprised of an adhesive or an encapsulant material such as EVA, the lamination process causes the ILD to seal the back of the solar cell 58 during the cell lamination. An additional encapsulant layer may be provided between the ILD and the solar cell or as an additional layer on the ILD that will seal over the back side of the solar cell during module lamination while the ILD remains fully in tact between the conductive wires and the back of the solar cell. The encapsulant layer is formed with openings over the back contacts on the back side of the solar cell so as to enable electrical connection of the solar cell back contacts and the conductive circuitry on the surface of the chlorosulfonated polyolefin containing back-sheet substrate 32. The encapsulant layer is typically comprised of an acid copolymer, an ionomer derived therefrom, or a combination thereof. The encapsulant layers typically have a thickness greater than or equal to 10 mils, and preferably greater than 20 mils. The encapsulant layer may be a film or sheet comprising poly(vinyl butyral)(PVB), ionomers, ethylene vinyl acetate (EVA), poly(vinyl acetal), polyurethane (PU), PVC, metallocene-catalyzed linear low density polyethylenes, polyolefin block elastomers, ethylene acrylate ester copolymers, such as poly(ethylene-co-methyl acrylate) and poly(ethylene-co-butyl acrylate), acid copolymers, or silicone elastomers. The encapsulant layer may further contain any additive known within the art. Such exemplary additives include, but are not limited to, plasticizers, processing aides, flow enhancing additives, lubricants, pigments, dyes, flame retardants, impact modifiers, nucleating agents to increase crystallinity, antiblocking agents such as silica, thermal stabilizers, hindered amine light stabilizers (HALS), UV absorbers, UV stabilizers, dispersants, surfactants, chelating agents, coupling agents, adhesives, primers, reinforcement additives, such as glass fiber, fillers and the like.

A process for forthing a back contact solar cell module with a solar cells connected in series by the integrated back-sheet is shown in FIGS. 5a-5f. According to this process, a front encapsulant layer 74 is provided as shown in FIG. 5a. The front encapsulant layer may be comprised of one of the encapsulant or adhesive sheet materials described above with regard to the optional encapsulant layer between the ILD and the back of the solar cells. The front encapsulant layer may be an independent self supporting sheet that can be adhered on its front side to a transparent front sheet (not shown) such as a glass or polymer front sheet, or it may be a sheet, coating or layer already adhered on a transparent front sheet. As shown in FIG. 5b, an array of back contact solar cells 76 and 78 are placed on the surface of the encapsulant layer 74 opposite to the front sheet side of the encapsulant layer. The solar cells 76 and 78 are placed with their front light receiving sides facing against the front encapsulant layer 74. Each of the solar cells has columns of positive and negative polarity back contacts with the negative contacts represented by the lighter circles 79 and the positive contacts represented by darker circles 80 in FIG. 5b. In the cells 76, in each pair of back contacts, a positive contact 80 is to the right of a negative contact 79. The cells 78 are rotated 180 degrees such that in each pair of back contacts, a negative contact 79 is to the right of one of the positive contacts 80. The cells 76 alternate with the cells 78 in both the vertical and horizontal directions of the solar cell array. It is contemplated that in other embodiments, there could be more of the positive or more of the negative contacts on the solar cells, or that there could be more or fewer columns of either the positive or negative back contacts. While FIG. 5b shows a cell 76 in the upper left hand corner of the solar cell array, it is contemplated that the cells could be arranged with a cell 78 in the upper left hand corner and with a cell 76 arranged below and next to the upper left hand corner cell 78. While the solar cell placements 76 and 78 are shown as alternating in both the vertical and horizontal directions of the array, it is also contemplated that in an array of series connected solar cells, the cell placements 76 and 78 could be alternated only in the vertical direction.

In FIG. 5c, an ILD 82 is placed over the back of the solar cell array. The ILD may be comprised of any of the materials described above with regard to the ILD 50 shown in FIG. 4b. The ILD 82 preferably has a thickness of about 1 to 10 mils. Holes 84 are preformed, cut or punched in the ILD 82 over where the back contacts of the solar cell array will be located. In FIG. 5d, the holes or openings in the ILD 82 are shown filled with a conductive adhesive dabs 85 which may be screen printed in the holes 84 of the ILD 82, or alternatively may be applied by syringe or other application method.

In FIG. 5e, the chlorosulfonated polyolefin containing back-sheet 32 with longitudinally extending wires 42 and 44 on the back-side are provided and applied over the ILD 82. The wires 42 and 44 are provided over sets of positive and negative back contacts on the solar cells. The side of the back-sheet 32 on which the wires are exposed is positioned so that the conductive wires 42 and 44 contact the conductive adhesive dabs 85 in the holes of the ILD 82.

As shown in FIGS. 5e and 5f, one of the wires 42 and 44 have been selectively cut between each set of solar cells in a column of solar cells in the solar cell array. The wires may be cut by mechanical die cutting, rotary die cutting, punching, mechanical drilling, laser ablation, or other known methods. As shown in FIG. 5e, the wires 42 are positioned over columns of the solar cell back-contacts 79 of negative polarity of the solar cell 76 that can be seen in FIG. 5b in the upper left corner of the solar cell array, and the wires 44 are positioned over the columns of back-contacts 80 of positive polarity of the solar cell 76 shown in FIG. 5b in the upper left corner of the solar cell array. The wires 42 are cut between where the wires 42 contact the solar cell 76 and where they contact the solar cell 78 which has been rotated 180 degrees and that is positioned below the cell 76. The wires 44 which positioned over the positive polarity contacts on the upper left solar cell 76 runs continuously over the negative contacts on the solar cell 78 positioned below the upper left solar cell 76 so as to connect the positive polarity contacts of the one cell in series to the negative polarity contacts of the next cell. The wires 44 are cut between where the wires 44 are positioned over the cell 78 and where they are positioned over the next cell 76 at the bottom right side of the solar cell array that can be seen in FIG. 5b. On the other hand, the wires 42 that are positioned over the positive polarity contacts of the middle cell in the left hand column of the solar cell array run continuously to where the wires 42 are positioned over the negative contacts of the solar cell 76 at the bottom right side of the solar cell array as can be seen in FIG. 5b. This pattern is repeated for as many solar cells as there are in the columns of the solar cell array.

FIG. 5f shows the application of bus connections 94, 96, and 98 on the ends of the back-sheet. The terminal buss 94 connects to the wires 44 that are over and will connect to the positive back-contacts on the solar cell at the bottom left hand side of the solar cell array. Likewise, the terminal buss 98 connects to the wires 44 that are over the negative back-contacts on the solar cell at the bottom right hand side of the solar cell array. Positive terminal buss 94 is connected to a positive lead 93 and the negative terminal buss 98 is connected to a negative lead 97. The intermediate buss connectors 96 connect the positive or negative back contacts at the top or bottom of one column of solar cells to the oppositely charged contacts at the same end of the adjoining column of solar cells. The terminal buss connections may alternately be extended through the “Z” direction out through the back-sheet. This would eliminate the need for extra space at the ends of the module for running the buss wires to the junction box. Such “extra space” would reduce the packing density of the cells and reduce the electric power output per unit area of the module.

The solar cell array shown in FIG. 5 is simplified for purpose of illustration and shows only four columns of three solar cells, and each solar cell is shown with just three columns of positive and three columns of negative back contacts. It is contemplated that the solar cell array of the solar module could have many more columns or rows of individual solar cells, and that each solar cell could have fewer or more columns or rows of back contacts than what is shown in FIG. 5.

The photovoltaic module of FIG. 5 may be produced through autoclave and non-autoclave processes. For example, the photovoltaic module constructs described above may be laid up in a vacuum lamination press and laminated together under vacuum with heat and standard atmospheric or elevated pressure. In one embodiment, a glass sheet, a front-sheet encapsulant layer, a back-contact photovoltaic cell layer, an ILD, and a chlorosulfonated polyolefin back-sheet with integrated longitudinally extending wires, as disclosed above, are laminated together under heat and pressure and a vacuum (for example, in the range of about 27-28 inches (689-711 mm) Hg) to remove air.

A process for manufacturing the photovoltaic module with a CSPE-containing back-sheet substrate will now be disclosed. The photovoltaic module may be produced through a vacuum lamination process. For example, the photovoltaic module constructs described above may be laid up in a vacuum lamination press and laminated together under vacuum with heat and standard atmospheric or elevated pressure. In an exemplary process, a glass sheet, a front-sheet encapsulant layer, a back-contact photovoltaic cell layer, an optional ILD layer, a back-sheet encapsulant layer and a wire embedded CSPE-containing back-sheet as described above are laminated together under heat and pressure and a vacuum to remove air. Preferably, the glass sheet has been washed and dried. In the procedure, the laminate assembly of the present invention is placed onto a platen of a vacuum laminator that has been heated to about 120° C. The laminator is closed and sealed and a vacuum is drawn in the chamber containing the laminate assembly. After an evacuation period of about 6 minutes, a silicon bladder is lowered over the laminate assembly to apply a positive pressure of about 1 atmosphere over a period of 1 to 2 minutes. The pressure is held for about 14 minutes, after which the pressure is released, the chamber is opened, and the laminate is removed from the chamber.

If desired, the edges of the photovoltaic module may be sealed to reduce moisture and air intrusion by any means known within the art. Such moisture and air intrusion may degrade the efficiency and lifetime of the photovoltaic module. Edge seal materials include, but are not limited to, butyl rubber, polysulfide, silicone, polyurethane, polypropylene elastomers, polystyrene elastomers, block elastomers, styrene-ethylene-butylene-styrene (SEBS), and the like.

The described process should not be considered limiting. Essentially, any lamination process known within the art may be used to produce the back contact photovoltaic modules with integrated back circuitry as disclosed herein.

While the presently disclosed invention has been illustrated and described with reference to preferred embodiments thereof, it will be appreciated by those skilled in the art that various changes and modifications can be made without departing from the scope of the present invention as defined in the appended claims.

### EXAMPLES

The following Examples are intended to be illustrative of the present invention, and are not intended in any way to limit the scope of the present invention described in the claims.

### Test Methods

### Damp Heat Exposure

Damp heat exposure is followed by a peel strength test. The substrate samples with embedded wires are made with at least one end where at least one end of the wires are not embedded in the substrates (“free ends”) for use in peel strength testing. Each sample strip has a section with the wire embedded that is at least four inches long and has a free end.

The samples are placed into a dark chamber. The samples are mounted at approximately a 45 degree angle to the horizontal. The chamber is then brought to a temperature of 85° C. and relative humidity of 85%. These conditions are maintained for a specified number of hours. Samples are removed and tested after about 1000 hours of exposure, because 1000 hours at 85° C. and 85% relative humidity is the required exposure in many photovoltaic module qualification standards.

After 1000 hours in the heat and humidity chamber, the sample strips were removed for peel strength testing. Peel strength is a measure of adhesion between wire and substrate. The peel strength was measured on an Instron mechanical tester with a 50 kilo loading cell using ASTM D3167.

### Temperature Cycle Test

The Temperature Cycle Test simulates thermal stresses on materials as a result of extreme temperature changes. According to the standard conditions of the IEC 61215 PV material test method, samples are subjected to 240 thermal cycles in a test chamber. The temperature cycling is followed by a peel strength test. The substrate samples with embedded wires were made with at least one end where at least one end of the wires are not embedded in the substrates (“free ends”) for use in peel strength testing. Each sample strip had a section with the wire embedded that was at least four inches long and had a free end. The samples were placed in the test chamber and each temperature cycle started at room temperature. The temperature was gradually reduced to −40° C. and held at that temperature for at least 10 minutes. The temperature was then gradually increased to 85° C. and held that that temperature for at least 10 minutes. The temperature was then gradually reduced back to room temperature and the cycle was repeated without pause. The rate of temperature reduction and temperature increase maintained at less than 100° C. per hour. The maximum length of each complete temperature cycle was 6 hours. The samples were subjected to about 240 thermal cycles. After temperature cycling, the peel strength of the samples was measured on an Instron mechanical tester with a 50 kilo loading cell using ASTM D3167.

### Preparation of Test Sample Substrate Slabs

The ingredients listed in Table 1 were mixed in a tangential BR Banbury internal mixer made by Farrel Corporation of Ansonia, Connecticut. The non-polymer additives were charged into the mixing chamber of the Banbury mixer and mixed before the chlorosulfonated polyethylene (CSPE) polymer and any thermoplastic polymer adhesive or rosin tackifier ingredients were introduced into the mixing chamber, in what is know as an upside down mixing procedure. The CSPE and the adhesives or tackifiers used were selected so as to have a softening point or melting point below 95° C.-100° C. in order to achieve good dispersion. The ingredient quantities listed in Table 1 are by weight parts relative to the parts CSPE and other ingredients used in each of the examples.

The speed of the Banbury mixer's rotor was set to 75 rpm and cooling water at tap water temperature was circulated through a cooling jacket around the mixing chamber and through cooling passages in the rotor. The cooling water was circulated to control the heat generated by the mixing. The temperature of the mass being compounded was monitored during mixing. After all of the ingredients were charged into the mixing chamber and the temperature of the mass reached 82° C., a sweep of the mixing chamber was done to make sure that all ingredients were fully mixed into the compounded mass. When the temperature of the compounded mass reached 120° C., it was dumped from the mixing chamber into a metal mold pan.

The compounded mass in the mold pan was then sheeted by feeding the mixture into a 16 inch two roll rubber mill. Mixing of the compound was finished on the rubber mill by cross-cutting and cigar rolling the compounded mass. During sheeting, the mass cooled.

Sample slabs were prepared by re-sheeting the fully compounded mass on a two roll rubber mill in which the rolls were heated to 80° C. The compound was run between the rolls from five to ten times in order to produce a 25 mil (0.64 mm) thick sheet with smooth surfaces. Six inch by six inch (15.2 cm by 15.2 cm) pre-form squares were die cut from the sheet. A number of the pre-forms were put in a compression mold heated to 100° C., and the mold was put into a mechanical press and subjected to pressure. The mold pressure was initially applied and then quickly released and reapplied two times in what is known as bumping the mold, after which the mold pressure was held for 5 minutes. Cooling water was introduced into the press platens in order to reduce the mold temperature. When the mold cooled to 35° C., the press was opened and the sample substrate slabs were removed.

TABLE 1

| Sample No. | 1 | 2 | 3 | 4 | 5 | 6 | 7 |
|---|---|---|---|---|---|---|---|
| CSPE | 100 | 100 | 100 | 70 | 70 | 70 | 100 |
| Hot Melt Polymer | | 30 | | | | | |
| Adhesive | | | | | | | |
| Hydrogenated Rosin | | | 30 | | | | |
| A Tackifier | | | | | | | |
| Ethylene-Butyl | | | | 30 | | | |
| Acrylate Copolymer | | | | | | | |
| Ethylene Vinyl | | | | | 30 | | |
| Acetate Copolymer | | | | | | | |
| Ethylene-Methyl | | | | | | 30 | |
| Acrylate Copolymer | | | | | | | |
| Hydrogenated Rosin | | | | | | | 30 |
| B Tackifier | | | | | | | |
| Ground Calcium | 85 | 85 | 85 | 85 | 85 | 85 | 85 |
| Carbonate | | | | | | | |
| Titanium Dioxide | 35 | 35 | 35 | 35 | 35 | 35 | 35 |
| Antioxidant | 1 | 1 | 1 | 1 | 1 | 1 | 1 |
| Polyethylene Glycol | 2 | 2 | 2 | 2 | 2 | 2 | 2 |
| Stearamide | 1.5 | 1.5 | 1.5 | 1.5 | 1.5 | 1.5 | 1.5 |
| Magnesium Oxide | 6 | 6 | 6 | 6 | 6 | 6 | 6 |
| UV Stabilizer | 0.8 | 0.8 | 0.8 | 0.8 | 0.8 | 0.8 | 0.8 |
| Total Parts | 231.3 | 261.3 | 261.3 | 231.3 | 231.3 | 261.3 | 261.3 |
| Density (kg/l) | 1.647 | 1.528 | 1.533 | 1.597 | 1.614 | 1.601 | 1.549 |
| Tg (° C.) | −25 | −23 | −14 | −22 | −24 | −23 | −14 |
| Tc (°C.) | 57 | 55 | 47 | 90 | 66 | 83 | 46 |
| Melt Temp (° C.) | 54 | 55 | 54 | 56 | 57 | 56 | 54 |

Ingredient Glossary

| | |
|---|---|
| CSPE | Hypalon ® 45 chlorosulfonated polyethylene |
| | from E. I. du Pont de Nemours and |
| | Company, of Wilmington, Delaware, USA |
| | (“DuPont”) |
| Hot Melt Polymer | Euromelt 707 US synthetic hot melt polymer |
| Adhesive | adhesive from Henkel Corporation of |
| | Dusseldorf, Germany |
| Hydrogenated | FloraRez 485 glycerol ester hydrogenated |
| Rosin A Tackifier | rosin tackifier from Florachem Corporation |
| Ethylene-Butyl | Elvaloy 3517-Si ethylene-butyl acrylate |
| Acrylate Copolymer | copolymer thermoplastic resin from DuPont |
| Ethylene Vinyl | Elvax 360 ethylene-vinyl acetate copolymer |
| Acetate | thermoplastic resin from DuPont |
| Ethylene-Methyl | Bynel 22E757 ethylene-methyl acrylate |
| Acrylate Copolymer | copolymer thermoplastic resin from DuPont |
| Hydrogenated | Stabelite Ester-E hydrogenated rosin-based |
| Rosin B Tackifier | tackifier from Eastman Chemical of |
| | Kingsport, Tennessee, USA |
| Ground Calcium | Atomite ® ground calcium |
| Carbonate | carbonate/limestone from Imerys of Roswell, |
| | Georgia |
| Titanium Dioxide | TiPure ® R-960 titanium dioxide from DuPont |
| Antioxidant | Irganox ® 1010 from BASF of Ludwigshafen, |
| | Germany [Benzenepropanoic acid, 3,5-bis(1,1- |
| | dimethyl)-4-hydroxy-2,2-bis[3-[3,5-bis(1,1- |
| | dimethylethyl)-4-hydroxyphenyl]-1- |
| | oxopropoxy]methyl]-1,3-propanediyl ester] |
| Polyethylene Glycol | Carbowax polyethylene glycol 3350 |
| | plasticizer from Dow Chemical Company of |
| | Midland, Michigan |
| Stearamide | Kemamide ® S stearamide processing aid |
| | from Chemtura Corporation of Middlebury, |
| | Connecticut |
| Magnesium Oxide | Elastomag ® 170 magnesium oxide post |
| | curing agent from Martin Marietta Magnesia |
| | Specialties LLC of Raleigh, North Carolina |
| UV Stabilizer | Tinuvin 622 LD butanedoic acid, dimethyl |
| | ester, polymer with 4-hydroxy-2,2,6,6- |
| | tetramethyl-1-piperidineethanol from from |
| | BASF of Ludwigshafen, Germany |

### Preparation and Testing of Back-Sheet Substrate Samples

Back-sheet samples were made using at least two sample substrates for each of the slab nos. 1 to 7 of Table 1 above. A 5 mil (127 μm) thick release sheet made of Teflon® PTFE was provided. Eight inch (20.3 cm) long solar cell tabbing wires with a thickness of about 160 mils (4.1 mm) were also provided. For each sample substrate slab, five of the 8 inch long solar cell tabbing wires were arranged parallel to each other and spaced about 1 inch (2.54 cm) from each other on the release sheet. The 25 mil (0.64 mm) thick single layer CSPE substrate sample slabs were each placed over five of the spaced wires. Each of the CSPE-containing substrates were six inch by six inch (15.2 cm by 15.2 cm) pre-form squares such that all of the wires overhung the opposite ends of each substrate by about an inch (2.54 cm) and the outside most wires were spaced in about an inch (2.54 cm) from the edges of each substrate. The assemblies were placed into a lamination press having a platen heated to about 120° C. The assemblies were allowed to rest on the platen for about 6 minutes to preheat the structures under vacuum. The lamination press was activated and the assemblies were pressed using 1 atmosphere of pressure for 14 minutes. When heat and pressure were removed, the wires had been partially embedded in surface of the CSPE sample substrates.

The peel strength between one of the wires on each set of substrate samples for each of the slabs 1-7 of Table 1 was measured as described above to obtain an initial peel strength for the wire on the sample. The initial peel strength for each slab (Examples 1-7) is reported on Table 2. One of the sample substrates for each of the slabs of Table 1 was subjected to the damp heat exposure test described above for 1000 hours and then three or four wires on the sample were tested for peel strength. The average peel strength after damp heat exposure is reported on Table 2 below. One of the sample substrates for each of the slabs of Table 1 was subjected to the temperature cycling test described above and then three or four wires on the sample were tested for peel strength. The average peel strength after temperature cycling is reported on Table 2 below.

TABLE 2

| Example No. | 1 | 2 | 3 | 4 | 5 | 6 | 7 |
|---|---|---|---|---|---|---|---|
| Table 1 sample no. | 1 | 2 | 3 | 4 | 5 | 6 | 7 |
| Initial peel strength | 3.68 | 3.76 | 23.84 | 8.29 | 6.84 | 16.08 | 12.35 |
| (kg/in) | | | | | | | |
| Peel strength after | 10.16 | 9.30 | 29.60 | 15.21 | 35.54 | 24.20 | 17.88 |
| 1000 hrs damp heat | | | | | | | |
| (kg/in) | | | | | | | |
| Peel strenght after | 5.39 | 8.64 | 48.41 | 20.55 | 22.51 | 24.54 | 21.24 |
| temperature cycling | | | | | | | |
| (kg/in) | | | | | | | |

What is claimed is:

1. An integrated back-sheet for a solar cell module with a plurality of electrically connected solar cells, comprising:
a homogeneous polymeric substrate having opposite first and second surfaces, said polymeric substrate having a thickness of at least 0.25 mm, said polymeric substrate comprising 20 to 95 weight percent chlorosulfonated polyolefin based on the weight of the polymeric substrate, and 1 to 50 weight percent of adhesive based on the weight of the polymeric substrate, said adhesive being selected from thermoplastic and thermoset polymer adhesives and rosin based tackifiers;
a plurality of electrically conductive metal wires disposed directly on said first surface of said homogeneous polymeric substrate, said metal wires being at least partially embedded in the first surface of said polymeric substrate, said homogeneous polymeric substrate adhering to said metal wires; and
wherein the second surface of said homogeneous polymeric substrate is an exposed surface.

2. The integrated back-sheet of claim 1 wherein said homogeneous polymeric substrate has a thickness of from 0.4 to 1.25 mm.

3. The integrated back-sheet of claim 1 wherein said homogeneous polymeric substrate comprises 25 to 90 weight percent chlorosulfonated polyethylene, and 5 to 35 weight percent of adhesive selected from thermoplastic polymer adhesives and rosin based tackifiers.

4. The integrated back-sheet of claim 1 wherein the chlorosulfonated polyolefin is a chlorosulfonated polyethylene having the formula 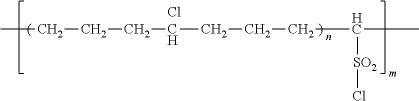
where m and n are positive integers of about 5-25.

5. The photovoltaic module of claim 4 wherein the chlorosulfonated polyethylene has a weight average molecular weight of about 75,000 to 300,000.

6. The integrated back-sheet of claim 1 wherein said polymeric substrate further comprises 10 to 70 weight percent of inorganic particulates based on the weight of the polymeric substrate.

7. The integrated back-sheet of claim 6 wherein said inorganic particulates are selected from the group of calcium carbonate, titanium dioxide, kaolin and clays, alumina trihydrate, talc, silica, antimony oxide, magnesium hydroxide, barium sulfate, mica, vermiculite, alumina, titania, wollastinite, boron nitride, and combinations thereof.

8. The integrated back-sheet of claim 1 wherein said conductive metal wires are comprised of metal selected from copper, nickel, tin, silver, aluminum, and combination thereof.

9. The integrated back-sheet of claim 1 wherein said conductive metal wires comprise a plurality of metal wires each extending at least two times the length of a solar cell in the solar cell module.

10. The integrated back-sheet of claim 1 wherein the metal wires are ribbon shaped metal wires having a width and thickness wherein the wire width is at least three times greater than the wire thickness.

11. The integrated back-sheet of claim 1 wherein the adhesive of said polymeric substrate comprises one or more rosin based tackifiers.

12. The integrated back-sheet of claim 1 wherein the adhesive of said polymeric substrate comprises an ethylene copolymer.

13. The integrated back-sheet of claim 1 wherein the plurality of electrically conductive metal wires adhered to the first side of said polymeric substrate each:
have a cross sectional area of at least 70 square mils along their length,
are substantially parallel to each other,
do not touch each other, and
extending at least two times the length of a solar cell in the solar cell module.

14. A back-contact solar module, comprising:
a front light emitting substrate;
a solar cell array of at least four solar cells each having a front light receiving surface, an active layer that generates an electric current when said front light receiving surface is exposed to light, and a rear surface opposite said front light receiving surface, said rear surface having positive and negative polarity electrical contacts thereon, said front light receiving surface of each of the solar cells of the solar cell array being disposed on said front light emitting substrate,
a homogeneous polymeric substrate having opposite first and second surfaces, said polymeric substrate having a thickness of at least 0.25 mm, said polymeric substrate comprising 20 to 95 weight percent chlorosulfonated polyolefin based on the weight of the polymeric substrate, and 1 to 50 weight percent of adhesive based on the weight of the polymeric substrate, said adhesive being selected from thermoplastic and thermoset polymer adhesives and rosin based tackifiers, the second surface of said homogeneous polymeric substrate forming an exposed surface of the solar module;
a plurality of electrically conductive metal wires disposed directly on said first surface of said homogeneous polymeric substrate, said metal wires being at least partially embedded in the first surface of said polymeric substrate, said homogeneous polymeric substrate adhering to said metal wires;
wherein the positive and negative polarity electrical contacts on the rear surface of said solar cells of said solar cell array are physically and electrically connected to said electrically conductive metal wires disposed on the first surface of the polymeric substrate.

15. The back-contact solar module of claim 14, further comprising
a polymeric interlayer dielectric layer having opposite first and second sides disposed between said electrically conductive metal wires on the back-sheet and the rear surface of the solar cells of the solar cell array, said polymeric interlayer dielectric layer having openings arranged in a plurality of columns, said interlayer dielectric layer adhered on its first side to the rear surface of the solar cells of the solar cell array and on its second side to the first side of said polymeric substrate over said conductive metal wires, wherein the plurality of columns of openings in said interlayer dielectric layer are arranged over the conductive wires adhered to the first side of the polymeric substrate such that the openings in each column of openings are aligned with and over one of the plurality of electrically conductive wires, and wherein the openings in said interlayer dielectric layer are aligned with the positive and negative polarity contacts on the rear surfaces solar cells of the solar cell array, wherein said positive and negative polarity electrical contacts on the rear surfaces of said solar cells are electrically connected to said conductive wires through the openings in said polymeric interlayer dielectric layer.

16. The back-contact solar module of claim 14 wherein said homogeneous polymeric substrate comprises 25 to 90 weight percent chlorosulfonated polyethylene, and 5 to 35 weight percent of adhesive selected from thermoplastic polymer adhesives and rosin based tackifiers.

17. The back-contact solar module of claim 14 wherein the chlorosulfonated polyolefin is a chlorosulfonated polyethylene having the formula 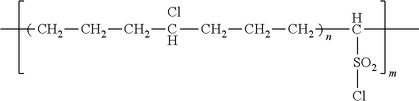
where m and n are positive integers of about 5-25.

18. The back-contact solar module of claim 17 wherein the chlorosulfonated polyethylene has a weight average molecular weight of about 75,000 to 300,000.
